(19) United States
(12) Patent Application Publication
(10) Pub. No.: US 2024/0063321 A1
(43) Pub. Date: Feb. 22, 2024

(54) APPARATUS HAVING A SINGLE PHOTON AVALANCHE DIODE (SPAD) WITH IMPROVED NEAR INFRARED (NIR) PHOTON DETECTION EFFICIENCY

(71) Applicant: KONINKLIJKE PHILIPS N.V., EINDHOVEN (NL)

(72) Inventor: THOMAS FRACH, AACHEN (DE)

(21) Appl. No.: 18/275,026

(22) PCT Filed: Feb. 7, 2022
(86) PCT No.: PCT/EP2022/052866

§ 371 Date: Jul. 31, 2023

Related U.S. Application Data
(60) Provisional application No. 63/146,657, filed on Feb. 7, 2021.

(51) Int. Cl. H01L 31/107; G01J 1/44; H01L 27/144; H01L 31/0232

(52) U.S. Cl. CPC H01L 31/107; G01J 1/44; H01L 27/1446; H01L 31/02327; G01J 2001/442; G01J 2001/446; G01J 2001/448

(57) ABSTRACT

A detector array (200) (200) according to the present teachings includes: a substrate (101) (101) adapted to function as a core layer of an optical waveguide (210) (210); a plurality of single photon avalanche photodiodes (SPAD (100)s (201)) disposed along a width of the substrate (101); a first cladding layer (202) (202) disposed over the plurality of SPADs (201) and along the width; and a second cladding layer (206) (206) disposed above the substrate and along the width.

### BACKGROUND

With the advent of light detection and ranging (LiDAR) systems currently being developed for Advanced Driver Assistance Systems (ADAS), there is a need for a reliable detector adapted for use in the preferred wavelength ranges used for these systems.

Due to the open nature of these systems, the output power and wavelengths of light from laser sources must be selected to avoid harm to living creatures in the surroundings. As such, in many current implementations, the wavelength of choice for the LiDAR sources generally falls in the near infrared (NIR) or infrared ranges with increasing power towards the infrared end of the spectrum to prevent eye damage.

Selection of proper detectors for use in the ADAS systems being developed poses a challenge. One viable candidate is a single photon avalanche diode (SPAD). SPADs can be implement in silicon, and while infrared detectors cannot be realized in silicon with its band gap of 1.1 eV, NIR (800 nm-1000 nm) can be covered by silicon-based SPADs.

Unfortunately, many known silicon-based SPADs are not useful for LiDAR detection. The main problem of NIR silicon detectors is that of absorption depth. The absorption depth of photons in silicon depends in the wavelength and as photon energy approaches the band gap, the absorption depth increases considerably. This increased absorption depth is problematic in application. Specifically, in order to detect single photons with high detection efficiency in the NIR, the SPAD junction has to be of considerable width (several 10 μm). This in turn leads to high breakdown voltages of several 100V and also puts limit on the timing jitter due to the uncertainty in position of the carrier generation (about 10 ps per 1 μm).

One type of SPAD is an open junction SPAD. Open junction SPADs are not desirable in LiDAR systems not only because they have higher spread in the timing resolution due to the drift component mentioned above, but also because they exhibit a “diffusion tail” due to carriers generated in field-free regions of the diode/substrate and propagating by random walk processes towards the junction.

Another type of SPAD is known as a closed SPAD. A shallow junction SPAD has a closed, fully depleted, shallow junction that show better time resolution and strongly reduced diffusion tail. However, the shallow junction SPAD has, due to its limited silicon volume, low photon detection efficiency in the near infrared range of the spectrum.

What is needed, therefore, is an apparatus for detecting LiDAR signals that overcomes the shortcoming of the devices described above.

### SUMMARY

As described herein, various embodiments are directed generally to photodetectors and arrays of photodetectors useful in detection of NIR radiation. In accordance with representative embodiments, the photodetector(s) have integrated waveguides that foster efficient detection of radiation. While one application of the photodetectors and photodetector arrays of the present teachings are contemplated for use in LiDAR systems, this application is merely illustrative, and the present teachings may have applications in other fields where improving efficiency of SPAD devices is desired.

Generally, a detector array according to the present teachings comprises: a substrate adapted to function as a core layer of an optical waveguide; a plurality of single photon avalanche photodiodes (SPADs) disposed along a width of the substrate; a first cladding layer disposed over the plurality of SPADs and along the width; and a second cladding layer disposed above the substrate and along the width.

In certain representative embodiments, the substrate provides the second cladding layer of the waveguide.

In accordance with a representative embodiment, the plurality of SPADs comprises a first SPAD along a side of the detector array where radiation is incident, and a last SPAD disposed at an opposing side, wherein the first SPAD has a first width, the last SPAD has a last width, and the first width is smaller than the last width.

In accordance with a representative embodiment the plurality of SPADs further comprises an intermediate SPAD disposed between the first SPAD and the last SPAD, wherein the intermediate SPAD has an intermediate width that is greater than the first width and smaller than the last width.

In accordance with a representative embodiment, each of the SPADs comprises a junction region having a width in a range of approximately 10 μm to approximately 100 μm and a thickness in a range of approximately 1 μm and approximately 10 μm.

In accordance with a representative embodiment, the substrate comprises silicon.

In accordance with a representative embodiment the substrate comprises silicon on insulator (SOI).

In accordance with a representative embodiment the detector array further comprises a proximal end adjacent to a light source and adapted to receive light from the light source, wherein an input waveguide is disposed at the proximal end, and between the light source and a first SPAD.

In accordance with a representative embodiment the detector array further comprises an opposing end at an opposing end of the detector array from the proximal end, wherein an end layer comprising a material having an index of refraction that is less than an index of refraction of the core layer is disposed at the opposing end of the detector array.

Generally, a photodetector comprises: a substrate adapted to function as a core layer of an optical waveguide; a single photon avalanche photodiode (SPAD) disposed along a width of the substrate; a first cladding layer disposed over the single SPAD and along the width; and a second cladding layer disposed beneath the substrate and along the width, wherein the optical waveguide comprises the substrate, the first cladding layer and the second cladding layer.

In accordance with a representative embodiment the substrate of the photodetector comprises silicon.

In accordance with a representative embodiment the substrate comprises silicon on insulator (SOI).

In accordance with a representative embodiment, the SPAD comprises a junction region having a width in a range of approximately 10 μm to approximately 100 μm, and a thickness in a range of approximately 1 μm and approximately 10 μm.

In accordance with a representative embodiment the photodetector further comprises a proximal end adjacent to a light source and adapted to receive light from the light source, wherein an input waveguide is disposed at the proximal end, and between the light source and the SPAD.

In accordance with a representative embodiment, the photodetector detector further comprises an opposing end at opposing the proximal end, wherein an end layer comprising a material having an index of refraction that is less than an index of refraction of the core layer is disposed at the opposing end of the detector array.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 shows a cross-sectional view of a SPAD contemplated for use in accordance with a representative embodiment.

FIG. 2A shows a cross-sectional view of a detector array in accordance with a representative embodiment.

FIG. 2B shows a perspective view of the detector array of FIG. 2A.

FIG. 3A shows a cross-sectional view of a detector array in accordance with a representative embodiment.

FIG. 3B shows a perspective view of the detector array of FIG. 3A.

FIG. 4A shows a cross-sectional view of a photodetector in accordance with a representative embodiment.

FIG. 4B shows a perspective view of the photodetector of FIG. 4A.

FIG. 4C shows a perspective view of a photodetector in accordance with a representative embodiment.

### DETAILED DESCRIPTION

In the following detailed description, for the purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the inventive concept.

The terminology used herein is for purposes of describing particular embodiments only and is not intended to be limiting. As used in the specification and appended claims, the singular forms of terms ‘a’, ‘an’ and ‘the’ are intended to include both singular and plural forms, unless the context clearly dictates otherwise (such as below where a photodetector comprises a single SPAD). Additionally, the terms “comprises”, and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “coupled to”, or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

For purposes of explanation and not limitation, various representative embodiments disclosing specific details are set forth in order to provide a thorough understanding of the present teachings. Other embodiments may be utilized and derived from the disclosure, such that structural and logical substitutions and changes may be made without departing from the scope of the present drawings. Additionally, as noted above, the drawings are merely representational and may not be drawn to scale. Certain proportions within the illustrations may be exaggerated, while other proportions may be minimized. Accordingly, the disclosure and the figures are to be regarded as illustrative rather than restrictive.

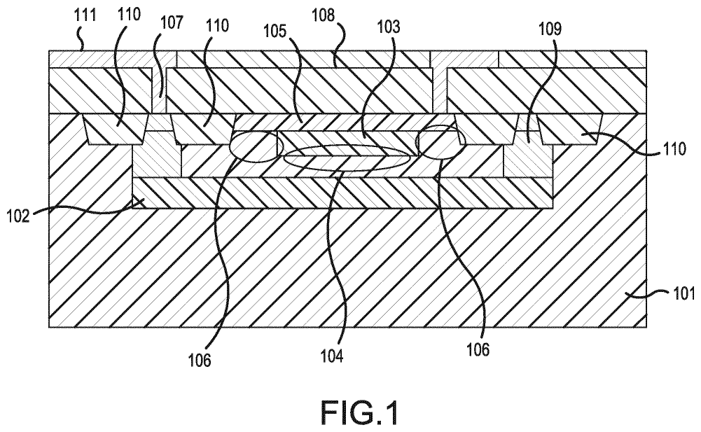

FIG. 1 shows a cross-sectional view of a SPAD 100 contemplated for use in accordance with a representative embodiment. The SPAD 100 comprises a substrate 101. The SPAD 100 is illustratively compatible with complementary metal oxide semiconductor (CMOS) processing and materials. Further details of the SPAD 100, its materials, and fabrication may be found in, for example, commonly owned U.S. Pat. No. 9,087,755 naming Thomas Frach inventors. Notably, and as described more fully below, the SPAD 100 may be disposed over a silicon-on-insulator (SOI) substrate (not shown in FIG. 1). Further details of the a SPAD formed over an SOI substrate, its materials, and fabrication may be found in, for example, commonly owned U.S. Pat. No. 7,714,292 to Agarwal, et al. A deep n-doped well 102 is formed in the substrate 101, and a high field (HF) implant 103 is formed over the deep n-doped well 102. This implant defines/creates the region with the high electric field that creates the avalanche when a free carrier is generated in this area/volume. The guard ring is implicitly created by keeping some distance between the perimeter of the device and the high field area. This is called “virtual guard ring”, though additional implants may be used in the guard ring area to make it more robust (i.e. further taper-off the fields or remove field spikes at the STI interface, which could otherwise lead to a failure of the guard ring and create edge breakdown of the device). A resulting avalanche region 104 is formed. An anode 105 is disposed over the HF implant 103, and completes the diode structure.

Guard rings 106 are disposed around the HF implant 103 and provide electrical isolation of the active region of the SPAD 100.

An electrical contact 107 provides an anode contact, and an electrical contact 108 provides a connection to the cathode of the SPAD 100. Shallow trench isolation 110 is provided as shown, and interconnects 112 complete the structure and enable electrical connections to other components on a wafer (not shown).

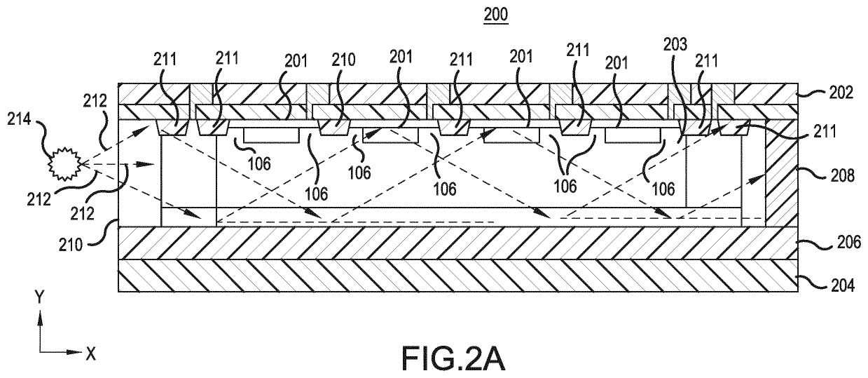

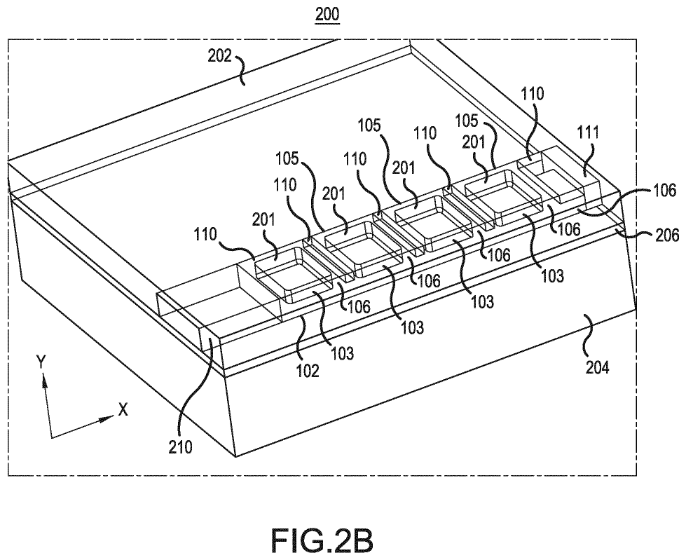

FIG. 2A shows a cross-sectional view of a detector array 200 in accordance with a representative embodiment. Various aspects and details of the SPAD 100 described above in connection with FIG. 1 are common to the detector array 200 of the presently described representative embodiments. These common aspects and details may not be repeated to avoid obscuring the description of the representative embodiments.

The detector array 200 comprises a plurality of SPADs 201 across its width. Each of the SPADs 201 illustratively comprises the same structure as SPAD 100.

A first cladding layer 202 disposed over the plurality of SPADs 201 and along the width; and a second cladding layer 206 disposed above a substrate 204 and along the width. A waveguide is provided by selecting materials for the first and second cladding layers 202, 206 having a refractive index that is less than an index of refraction of a core layer. Notably, region 203 between the first and second cladding layers 202, 206 is generally silicon, which is doped in certain regions to provide the various components of the SPADs 201. By contrast, the first and second cladding layers 202, 206 each comprise silicon oxide or other suitable material to provide the step in the index of refraction at the interfaces of the region 203 and the first and second cladding layers 202, 206. As such, in certain representative embodiments, region 203 provides the core layer between the first cladding layer 202 and the second cladding layer 206 of the waveguide of detector array. Notably, in accordance with a representative embodiment, the substrate 204 is thinned known backside processing techniques (grinding, chemical mechanical polishing (CP), etc.) to a desired thickness. Next, during backside processing silicon dioxide layers to provide the second cladding layer 206 are deposited over the substrate 204 (and thus are beneath the substrate 204) to provide the differential step in the refractive index for reflection at their interface. Alternatively, the substrate 204 may be an SOI substrate that provides the oxide layer adjacent to the silicon layer used for the SPAD fabrication. As such, the oxide layer is embedded and protected, and thus from the practical standpoint, an SOI substrate facilitates processing of the detector array 200.

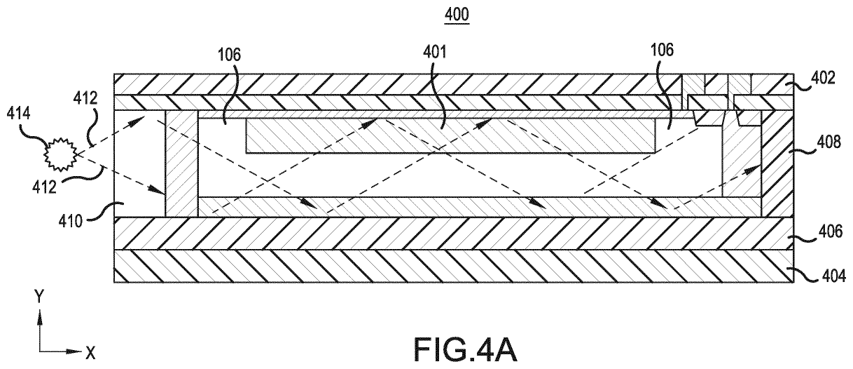

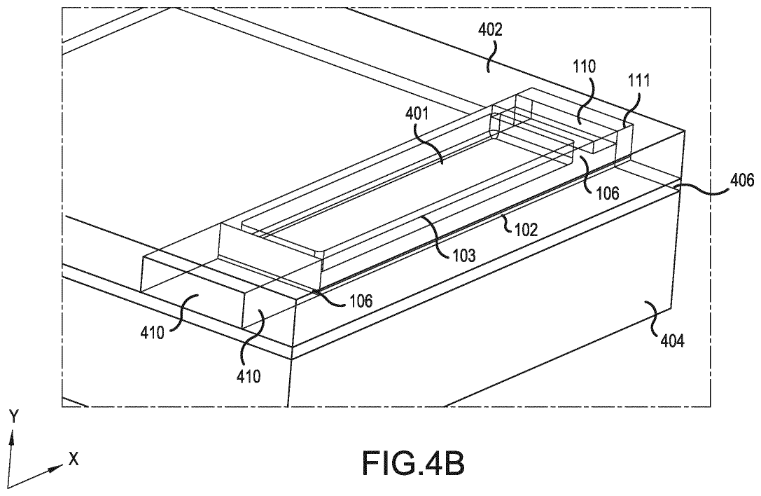

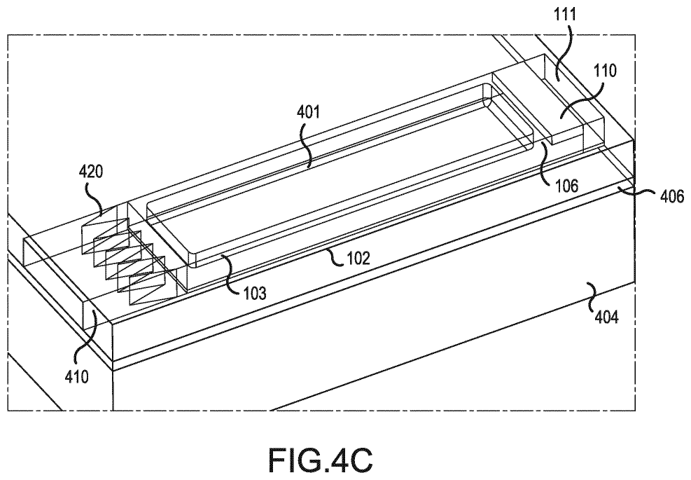

The detector array 200 further comprises an end layer 208 at a distal end of the detector array 200, and an input waveguide 210 at a proximal end. The input waveguide 210 usefully reduces losses due to reflections. The waveguide structure 210 comprises a silicon nitride layer 211 embedded in the first cladding layer 202. Notably, an anti-reflective coating can be provided at the interface 213 of the waveguide structure 210 and the silicon of the detector array 200, or by its geometry (e.g., see FIG. 4C and its description below), or a combination of both. The method also depends on the size of the waveguide and the propagation modes. Impedance matching of a mono-mode waveguide would look different compared to a multimode waveguide of the present teachings.

Generally, photons from a source 214 (e.g., an NIR source of a LiDAR detector) are coupled in by external optics (not shown) and are transmitted through a low-loss, high quality silicon nitride (SiN) input waveguide 210 (embedded in SiO₂) to the SPADs 201. Since the index refraction of SiN is 2.0 and the index of refraction of Si is approximately 3.7, there will be losses at the SiN—Si interface. To maximize sensitivity, there should be some antireflective (or matching) structure between these two waveguides. The way this is done depends on the type of waveguide (mono/multimode) and the compatibility with the CMOS process. Such a structure according to a representative embodiment is shown and described in connection with in FIG. 4C.

By contrast, the end layer 208, which is illustratively made of the same material as the first and second cladding layers 202, 206 (e.g., silicon dioxide), provides a step change in the index of refraction at the interface of the region 203 and the end layer 208. As a result, some of the photons 212 incident on the end layer 208 are reflected back towards the input waveguide 210. This improves the probability of a photon that would otherwise be lost, to be incident on an active region of one of the SPADs 201, and be absorbed. This is especially the case when the detector array is comparatively short (x-direction in the coordinate system shown) or if the SPADs 201 are short, or both. As such, by providing the end layer 208, the photon detection efficiency of the detector array 200 is improved.

Finally, if the detector array 200 is made long (x-direction in the coordinate system shown) enough (200-300 μm), the silicon at the end of the detector array 200 can seamlessly merge with the substrate carrying the readout electronics. For shorter detector arrays 200 (less than the absorption length), a reflector at the end of the SPAD could help to somewhat increase the sensitivity but it is not essential for the function.

FIG. 2B shows a perspective view of the detector array of FIG. 2A. Various aspects and details of the SPAD 100 and the detector array 200 of FIGS. 1 and 2A, respectively, are common to the detector array 200 of the presently described representative embodiments. These common aspects and details may not be repeated to avoid obscuring the description of the representative embodiments.

The detector array 200 comprises the plurality of SPADs 201 across its width (x-direction in the coordinate system of FIG. 2B). The first cladding layer 202 is disposed over the plurality of SPADs 201 and along the width (x-direction in the coordinate system of FIG. 2B); and the second cladding layer 206 disposed above a substrate 204 and along the width. A waveguide is provided by selecting materials for the first and second cladding layers 202, 206 having a refractive index that is less than an index of refraction of a core layer. Notably, region 203 between the first and second cladding layers 202, 206 is generally silicon, which is doped in certain regions to provide the various components of the SPADs 201. By contrast, the first and second cladding layers 202, 206 each comprise silicon oxide or other suitable material to provide the step in the index of refraction at the interfaces of the region 203 and the first and second cladding layers 202, 206. As such, in certain representative embodiments, region 203 provides the core layer between the first cladding layer 202 and the second cladding layer 206 of the waveguide of detector array. Notably, in accordance with a representative embodiment, the substrate 204 is thinned known backside processing techniques (grinding, chemical mechanical polishing (CMP), etc.) to a desired thickness.

As noted above, the deep n-doped well 102 is formed in the substrate 101, and a high field (HF) implant 103 is formed over the deep n-doped well 102. A resulting avalanche region is formed. Anodes 105 for the respective SPADs are disposed over the HF implant 103, and completes the diode structure. Finally, the independent electrical functions of the SPADs 201 is fostered by the inclusion of guard rings 106 disposed around the HF implants 103 and provide electrical isolation of the active region of the SPADs 201. As described more fully below, the guard rings have an impact on the overall detection efficient of the detector array 200. Optically, however, there is no difference between a guard ring 106 and the avalanche region 104 of the SPADs 201. However, there is also the top silicon surface (the surface to the anode 105 and cathode contact 109 (i.e., the top surface of the wafer that is not STI), which has active islands (avalanche regions 104) separated by shallow-trench isolation (STI). These different features cause the upper portion of the detector array 200 optically rough, leading to some photon scattering, which cause additional losses. The degree of such losses depends on various factors such as number of SPADs 201 (and thus guard rings 106) and the width/depth of the STI.

In fabrication, the detector array 200 is formed by providing the substrate 204, which, as noted above, is illustratively an SOI substrate. After formation of a silicon patch, the patch is selectively patterned, and high quality silicon nitride conformal layer (not shown) is deposited. Next, a chemical-mechanical polish (CMP) step is done to planarize the surface over which the detector array 200 is formed. An etching step is completed to form the lower portion of the waveguide. A layer of silicon dioxide is deposited to form the side cladding (see FIG. 2B) surrounding the detector array 200. A second CMP sequence is completed to planarize the surface for CMOS fabrication of the individual SPADs 201. The top cladding layer of SiO₂ is provided, and, is, illustratively a first inter-layer dielectric of a CMOS interconnect.

Alternatively, if a silicon substrate is used instead of an SOI, the silicon substrate has to be thinned down by backside processing (grinding, CMP, etching) to the right thickness in the range of approximately 1 μm to approximately 10 μm. and then the oxide layer to form the second cladding layer 206 of the detector array 200 is deposited on the backside to provide the step in the refractive index. Notably, a layer of silicon nitride can be deposited to protect and passivate the detector array 200. These steps are carried out after the front-side processing of the detector array 200 is completed and the wafer has been glued to a handler wafer. As can be appreciated, because SOI has the oxide layer already embedded and protected, the use SOI for the detector array 200 is beneficial.

In accordance with a representative embodiment, the plurality of SPADs 201 have the substantially same dimensions. As noted above, in operation, NIR photons propagate laterally (x-dimension in the coordinate system of FIGS. 2A, 2B) through the shallow (y-dimension in the coordinate system of FIGS. 2A, 2B) junction of each of the SPADs 201. However, because of the lateral propagation of light, the width (x-dimension) of the junction can extend over several 10 μm more easily in the lateral direction than into the substrate 204.

In operation, photons are reflected from first and second cladding layers 202, 206 and propagate in x direction of the coordinate system shown. As long as the photons propagate in silicon, they are absorbed and generate e-h pairs. the resulting SPAD will be narrow and long (e.g. 10×100 μm). As is known high aspect ratio SPADs add timing jitter due to the finite speed of avalanche spreading across the junction. However, it is possible to find the initial point of the breakdown with precision on the order of micrometers by sensing the SPAD at the two narrow sides and measuring the difference in time of arrival of the breakdown signals. In accordance with the certain representative embodiments, a long absorption region is partitioned into independent SPADs 201 (i.e., independent segments), which can break down independently and detect photons in different sections of the absorption region. Providing SPADs 201 according to the representative embodiments with comparatively small dimensions, beneficially reduces the timing jitter due to the substantially instantaneous breakdown of the entire junction, thereby improving the time resolution and increasing the spatial resolution of a LIDAR system that incorporates the detector array 200 of FIGS. 2A-2B as well as detector arrays of other representative embodiments described below.

Furthermore, due to comparatively low photoemission breakdown in one of the SPADs 201 of the detector array 200 has lower probability to trigger breakdowns in other SPADs 201 operating at the same channel. Specifically, photoemission occurs during the avalanche and about three optical photons are generated per 100k carriers crossing the junction. The number of generated carriers (gain of the SPAD) equals SPAD capacitance (including any parasitic components) times excess voltage (voltage above breakdown). SPAD capacitance is proportional to the area of the device and inversely proportional to the junction width. So SPADs with smaller area have proportionally smaller capacitance, their photoemission is lower and the probability of optical crosstalk is reduced. Lidar systems typically use arrays of detectors, with each directed to different parts of the scene to increase the frame rate of the system. Current LiDAR systems have tens to hundreds of detectors and scan the scene in many directions at the same time with proportionally higher frame rates. As such the other SPADs 201 in the detector array 200 remain available for photon detection. Stated somewhat differently, by “segmenting” a comparatively large single SPAD, the independent SPADs 201 of the detector array 200, operate independently, and thus in parallel. These independent SPADs 201 also have comparatively fast recovery times. So, through the guiding of photons 212 in the detector array 200, and the reflection of unabsorbed photons from end layer 208, a greater number of photons are available for absorption, and because of the reduced dead time afforded by the comparatively small shallow-junctions SPADs 201 of the detector array 200, the probability of photon absorption is improved compared to other known detectors. Moreover, because photons 212 in close proximity in time to one another have a greater likelihood of generating breakdowns in different SPADs 201 of the detector array 200, and are so separated in space by the absorption properties of silicon. This will improve photon detection efficiency by reducing the dead time of a LiDAR device comprising detector array 200. Finally, the loss of sensitivity due to dead segments (e.g., guard rings 106) between each of the SPADs 201 is comparatively small, and can be compensated by a slight increase of the excess voltage of the SPAD. Specifically, any photon absorbed in this region generates electron-hole carriers, which are swept out by the electric field in the guard rings 106 without generating an avalanche. As such, the guard rings needed for isolation of neighboring SPADs 201 will result in an increase the insensitive volume of the detector array 200. This is different by comparison to other types of photodiodes in which substantially all charge that is generated inside the photodiode contributes to the output signal. In a SPAD, the output signal consists of relatively small current due to the leakage of the SPAD through the guard ring (including any photogenerated current in the guard ring 106) superimposed with much larger pulses of avalanche current upon the detection of single photons in the avalanche region of the SPADs.

Notably, according to other representative embodiments described below, further improvements in photon detection efficiency are realized by various aspects of the present teachings.

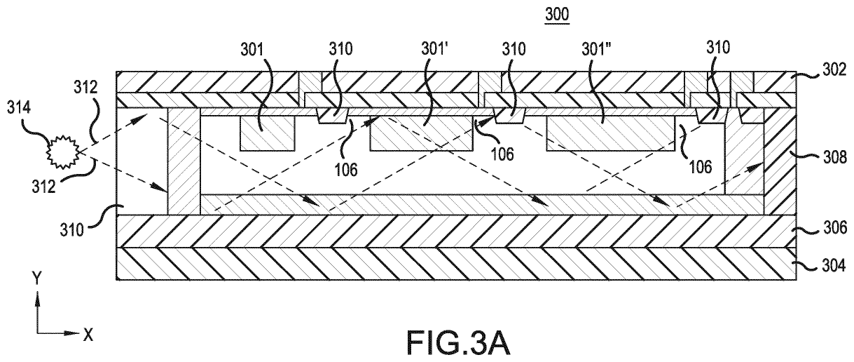

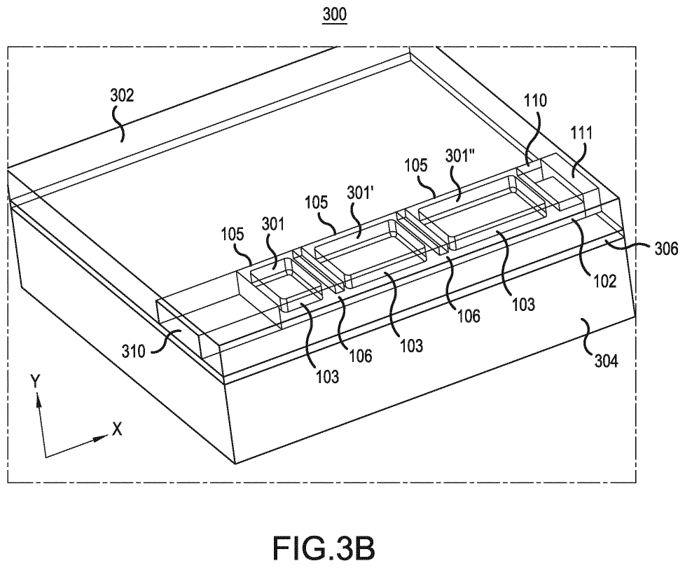

FIG. 3A shows a cross-sectional view of a detector array 300 in accordance with a representative embodiment. Various aspects and details of the SPAD 100 and the detector array 200 described above in connection with FIGS. 1 and 2A-2B are common to the detector array 300 of the presently described representative embodiments. These common aspects and details may not be repeated to avoid obscuring the description of the representative embodiments.

The detector array 300 comprises a plurality of SPADs 301, 301′, 301″ across its width (x-dimension in coordinate system shown). Each of the SPADs 301, 301′, 301″ illustratively comprises the same structure as SPAD 100. However, for reasons described more fully below, SPAD 301 has a first width (x-dimension), SPAD 301′ has a second width that is greater than the first width, and SPAD 301″ has a width that is greater that the second width. Notably, the width of the SPADs 301, 301′, 301″ are dependent on the wavelength-dependent absorption length. However, there are some additional constraints such as timing degradation, dark count noise, and space available for electronics/electrical connections. In accordance with a representative embodiment, the width of the SPADs 301, 301′, 301″ are successively exponentially greater, with the exponentially greater width being inversely proportional to the exponential decline in photons across the width of the detector array 300. Notably, the SPADs 301, 301′, 301″ have the same thickness (y-dimension in the coordinate system shown) for reasons substantively the same as the thicknesses of SPADs 201 described above.

A first cladding layer 302 disposed over the plurality of SPADs 301, 301′, 301″ and along the width; and a second cladding layer 306 disposed above a substrate 304 and along the width. A waveguide is provided by selecting materials for the first and second cladding layers 302, 306 having a refractive index that is less than an index of refraction of a core layer. Notably, region 303 between the first and second cladding layers 302, 306 is generally silicon, which is doped in certain regions to provide the various components of the SPADs 301, 301′, 301″. By contrast, the first and second cladding layers 302, 306 each comprise silicon oxide or other suitable material to provide the step in the index of refraction at the interfaces of the region 303 and the first and second cladding layers 302, 306. As such, in certain representative embodiments, region 303 provides the core layer between the first cladding layer 302 and the second cladding layer 306 of the waveguide of detector array. Notably, in accordance with a representative embodiment, the substrate 304 is thinned known backside processing techniques (grinding, chemical mechanical polishing (CMP), etc.) to a desired thickness. Next, during backside processing silicon dioxide layers are deposited to provide the second cladding layer 306 are deposited over the substrate 304 (and thus are beneath the substrate 304) to provide the differential step in the refractive index for reflection at their interface. Alternatively, the substrate 304 may be an SOI substrate that provides the oxide layer adjacent to the silicon layer used for the SPAD fabrication. As such, the oxide layer is embedded and protected, and thus from the practical standpoint, an SOI substrate facilitates processing of the detector array 300. Notably, during backside processing, silicon nitride may be deposited for passivation or as an ion barrier, for example.

The detector array 300 further comprises an end layer 308 at a distal end of the detector array 300, and an input waveguide 310 at a proximal end to provide a low-loss transition from the SiN waveguide to the (silicon) of the detector array 300.

As described below, in operation, the input waveguide 310 fosters reception of photons 312 from a source 314 (e.g., an NIR source of a LiDAR detector) to be guided through the waveguide made up of the core (silicon layer from which the SPADs 301, 301′, 301″ are made) and first cladding layers 302, 306.

By contrast, the end layer 308, which is illustratively made of the same material as the first and second cladding layers 302, 306 (e.g., silicon dioxide), provides a step change in the index of refraction at the interface of the region 303 and the end layer 308. As a result, some of the residual photons 312 incident on the end layer 308 are reflected back towards the input waveguide 310, particularly when the SPADs 301, 301′ and 301″ have comparatively short widths (x-direction in the coordinate axis of FIG. 3). Illustratively, the absorption length at 900 nm is approximately 60 μm. After traversing the waveguide of the detector array 300 by this distance, the number of photons drops to about ⅓. As such, increasing the width of the detector array (and of the individual SPADs 301, 301′, 301″) by approximately 200 μm to approximately 300 μm will result in the absorption of the majority of incident on the detector array 300. This improves the probability of a photon that would otherwise be lost, to be incident on an active region of one of the SPADs 301, 301′, 301″, and be absorbed. As such, by providing the end layer 308, the photon detection efficiency of the detector array 300.

FIG. 3B shows a perspective view of the detector array of FIG. 3A. Various aspects and details of the SPAD 100 of FIG. 1, and the detector arrays 200, 300 of FIGS. 2A-3B, are common to the detector array 300 of the presently described representative embodiments. These common aspects and details may not be repeated to avoid obscuring the description of the representative embodiments.

The detector array 300 comprises the plurality of SPADs 301, 301′, 301″ across its width (x-direction in the coordinate system of FIG. 3B). The first cladding layer 302 is disposed over the plurality of SPADs 301, 301′, 301″ and along the width (x-direction in the coordinate system of FIG. 3B); and the second cladding layer 306 disposed above a substrate 304 and along the width. A waveguide is provided by selecting materials for the first and second cladding layers 302, 306 having a refractive index that is less than an index of refraction of a core layer. Notably, region 303 between the first and second cladding layers 302, 306 is generally silicon, which is doped in certain regions to provide the various components of the SPADs 301, 301′, 301″. By contrast, the first and second cladding layers 302, 306 each comprise silicon oxide or other suitable material to provide the step in the index of refraction at the interfaces of the region 303 and the first and second cladding layers 302, 306. As such, in certain representative embodiments, region 303 provides the core layer between the first cladding layer 302 and the second cladding layer 306 of the waveguide of detector array. Notably, in accordance with a representative embodiment, the substrate 304 is thinned known backside processing techniques (grinding, chemical mechanical polishing (CMP), etc.) to a desired thickness.

As noted above, the deep n-doped well 102 is formed in the substrate 101, and a hydrogen-fluorine (HF) implant 103 is formed over the deep n-doped n-well 102. A resulting avalanche region results. Anodes 105 for the respective SPADs are disposed over the HF implant 103, and completes the diode structure. Finally, the independent electrical functions of the SPADs 301, 301′, 301″ are fostered by the inclusion of guard rings 106 disposed around the HF implants 103 and provide electrical isolation of the active region of the SPAD 100. As noted above, optically, however, there is no difference between a guard ring 106 and the avalanche region 104 of the SPADs 301. However, there is also the top surface of the detector array (silicon surface), which has active islands (avalanche regions 104) separated by shallow-trench isolation (STI). These different features cause the upper portion of the detector array 300 optically rough, leading to some photon scattering, which cause additional losses. The degree of such losses depends on various factors such as number of SPADs 301 (and thus guard rings 106) and the width/depth of the STI.

Because the photon absorption in is parallel to the top surface of the detector array 200, the resulting SPAD will be narrow (e.g., 10 μm thick) and long—generally five to six times the absorption length. So for a 905 nm detector array, the absorption length is approximately 60 μm, and the absorption length would be approximately 300 μm. As is known high aspect ratio SPADs add timing jitter due to the finite speed of avalanche spreading across the junction. However, it is possible to find the initial point of the breakdown with precision on the order of micrometers by sensing the SPAD at the two narrow sides and measuring the difference in time of arrival of the breakdown signals. In accordance with the certain representative embodiments, a long absorption region is partitioned into independent SPADs 301 (i.e., independent segments), which can break down independently and detect photons in different sections of the absorption region. Providing SPADs 301, 301′, 301″ according to the representative embodiments with comparatively small dimensions, beneficially reduces the timing jitter due to the substantially instantaneous breakdown of the entire junction, thereby improving the time resolution and increasing the spatial resolution of a LIDAR system that incorporates the detector array 300 of FIGS. 3A-3B as well as detector arrays of other representative embodiments described below. These independent SPADs 301 also have comparatively fast recovery times. So, through the guiding of photons 312 in the detector array 300, and the reflection of unabsorbed photons from end layer 308, a greater number of photons are available for absorption, and because of the reduced dead time afforded by the comparatively small shallow-junctions SPADs 301 of the detector array 300, the probability of photon absorption is improved compared to other known detectors. Moreover, because photons 312 in close proximity in time to one another have a greater likelihood of generating breakdowns in different SPADs 301 of the detector array 300, and are so separated in space by the absorption properties of silicon. This will improve photon detection efficiency by reducing the dead time of a LiDAR device comprising detector array 300. Finally, the loss of sensitivity due to dead segments (e.g., guard rings 106) between each of the SPADs 301 is comparatively small and can be compensated by increasing the excess voltage.

As noted above, the exponential absorption law of photons can be one of many criteria for the selection of the width of the SPADs 301, 301′, 301″. Another factor to be considered is time jitter due to the avalanche spreading because of the larger length of the SPADs (e.g., SPAD 301′ versus SPAD 301″) or the dark count noise of the larger SPAD segments or the space available for the digital electronics. So, for instance, the for the comparatively short SPADs 301 and 301′ the exponential absorption law can be used to determine their width, whereas the width of SPAD 301″ (or additional SPADs (not shown) having a greater width than SPAD 301″) may not be based on the exponential absorption law, but rather may be be limited in order to limit the timing jitter. Finally, and as alluded to above, the width of the SPADs 301, 301′, 301″ increases as shown. The photons 312 are entering the device from the left and are absorbed laterally along the length of each of the SPADs 301, 301′, 301″ as they are guided by the waveguide of the detector array (from left to right). It can be shown that photon intensity decreases in the waveguide from the input waveguide 310 to the end layer 308. Due to the exponential absorption of the photons across the SPADs 301, 301′, 301″, more are absorbed by SPAD 301 than SPAD 301′, and less by SPAD 301″ than SPAD 301′. In accordance with representative embodiments, the width (x-dimension in the coordinate system of FIGS. 3A, 3B) of each of the SPADs 301, 301′, 301″ is selectively increased so the number of photons incident on each SPAD 301, 301′, 301″ is approximately the same. This will lead to approximately equal utilization of each of the SPADs 301, 301′, 301″ (assuming each SPAD 301, 301′, 301″ has its own quench and recharge electronics, time to digital converter (TDC), counters, etc.)

FIG. 4A shows a cross-sectional view of a photodetector 400 in accordance with a representative embodiment. Various aspects and details of the SPAD 100 of FIG. 1, and the detector arrays 200, 300 of FIGS. 2A-3B, are common to the photodetector 400 of the presently described representative embodiments. These common aspects and details may not be repeated to avoid obscuring the description of the representative embodiments.

The photodetector 400 comprises a single SPAD 401. The single SPAD 401 illustratively comprises the same structure as SPAD 100.

A first cladding layer 402 disposed over the single SPAD 401 and along the width; and a second cladding layer 406 disposed above a substrate 404 and along the width. A waveguide is provided by selecting materials for the first and second cladding layers 402, 406 having a refractive index that is less than an index of refraction of a core layer. Notably, region 403 between the first and second cladding layers 402, 406 is generally silicon, which is doped in certain regions to provide the various components of the Single SPAD 401. By contrast, the first and second cladding layers 402, 406 each comprise silicon oxide or other suitable material to provide the step in the index of refraction at the interfaces of the region 403 and the first and second cladding layers 402, 406. As such, in certain representative embodiments, region 403 provides the core layer between the first cladding layer 402 and the second cladding layer 406 of the waveguide of detector array. Notably, in accordance with a representative embodiment, the substrate 404 is thinned known backside processing techniques (grinding, chemical mechanical polishing (CP), etc.) to a desired thickness. Next, during backside processing silicon dioxide layers to provide the second cladding layer 406 are deposited over the substrate 404 (and thus above the substrate 404) to provide the differential step in the refractive index for reflection at their interface. Alternatively, the substrate 404 may be an SOI substrate that provides the oxide layer adjacent to the silicon layer used for the SPAD fabrication. As such, the oxide layer is embedded and protected, and thus from the practical standpoint, an SOI substrate facilitates processing of the photodetector 400.

The photodetector 400 further comprises an end layer 408 at a distal end of the photodetector 400, and an input waveguide 410 at a proximal end, with an anti-reflective coating 413 disposed between the input waveguide 410 and the silicon of the photodetector 400.

As described below, in operation, the input waveguide 410 fosters reception of photons 412 from a source 414 (e.g., an NIR source of a LiDAR detector) to be guided through the waveguide made up of the core (silicon layer from which the Single SPAD 401 are made) and first and second cladding layers 402, 406.

By contrast, the end layer 408, which is illustratively made of the same material as the first and second cladding layers 402, 406 (e.g., silicon dioxide), provides a step change in the index of refraction at the interface of the region 403 and the end layer 408. As a result, photons 412 incident on the end layer 408 are reflected back towards the input waveguide 410. This improves the probability of a photon that would otherwise be lost, to be incident on an active region of one of the Single SPAD 401, and be absorbed. As such, by providing the end layer 408, the photon detection efficiency of the photodetector 400.

FIG. 4B shows a perspective view of the detector array of FIG. 4A. Various aspects and details of the SPAD 100, and the detector arrays 200, 300 of FIGS. 1-3B, and the photodetector 400 of FIG. 4A are common to the photodetector 400 of the presently described representative embodiments. These common aspects and details may not be repeated to avoid obscuring the description of the representative embodiments.

The photodetector 400 comprises the single SPAD 401 across its width (x-direction in the coordinate system of FIG. 4B). The first cladding layer 402 is disposed over the single SPAD 401 and along the width (x-direction in the coordinate system of FIG. 4B); and the second cladding layer 406 disposed above a substrate 404 and along the width. A waveguide is provided by selecting materials for the first and second cladding layers 402, 406 having a refractive index that is less than an index of refraction of a core layer. Notably, region 403 between the first and second cladding layers 402, 406 is generally silicon, which is doped in certain regions to provide the various components of the Single SPAD 401. By contrast, the first and second cladding layers 402, 406 each comprise silicon oxide or other suitable material to provide the step in the index of refraction at the interfaces of the region 403 and the first and second cladding layers 402, 406. As such, in certain representative embodiments, region 403 provides the core layer between the first cladding layer 402 and the second cladding layer 406 of the waveguide of detector array. Notably, in accordance with a representative embodiment, the substrate 404 is thinned known backside processing techniques (grinding, chemical mechanical polishing (CMP), etc.) to a desired thickness.

As noted above, the deep n-doped well 102 is formed in the substrate 101, and a high-field (HF) implant 103 is formed over the deep n-doped n-well 102. A resulting avalanche region is formed. Anodes 105 for the respective SPADs are disposed over the HF implant 103, and completes the diode structure. Finally, the independent electrical functions of the Single SPAD 401 is fostered by the inclusion of guard rings 106 disposed around the HF implant 103 and provide electrical isolation of the active region of the Single SPAD 401. As described more fully below, the guard rings 106 have an impact on the overall detection efficient of the photodetector 400. Optically, however, there is no difference between a guard ring 106 and the avalanche region 104 of the Single SPAD 401. However, there is also the top silicon surface (beneath first cladding layer 402) which has active islands (avalanche regions 104) separated by shallow-trench isolation (STI). These different features cause the upper portion of the photodetector 400 optically rough, leading to some photon scattering, which cause additional losses. The degree of such losses depends on various factors such as number of Single SPAD 401 (and thus guard rings 106) and the width/depth of the STI.

The Single SPAD 401 provides a highest “fill factor” compared to the SPADs described in connection with FIGS. 2A-3B. As such, the Single SPAD 401 has the greatest sensitive volume compared to total volume of the photodetector 400. However, the Single SPAD 401 has significant time jitter due to uncertainty in the position of avalanche start and associated spreading of the avalanche across the photodetector 400. Specifically, comparative small especially circular SPADs break down faster and the breakdown is a lot less dependent on the position of the origin. The Single SPAD 401 also has a higher dark count rate, hence a higher dead time when compared to the SPADs described in connection with representative embodiments in FIGS. 2A-3B. The single SPAD 401 also has a comparatively slower recharge time due to a high device capacitance compared to the SPADs described in connection with representative embodiments in FIGS. 2A-3B. This comparatively high intrinsic capacitance also causes higher optical crosstalk to neighboring. The after-pulsing probability of the Single SPAD 401 is also greater, and the Single SPAD 401 has a limited excess voltage range, limiting the PDE.

FIG. 4C shows a perspective view of a photodetector in accordance with a representative embodiment. Various aspects and details of the SPAD 100 of FIG. 1, and the detector arrays 200, 300 and photodetector 400 of FIGS. 2A-4B, are common to the photodetector 400 of the presently described representative embodiments. These common aspects and details may not be repeated to avoid obscuring the description of the representative embodiments.

The photodetector 400 comprises the single SPAD 401 across its width (x-direction in the coordinate system of FIG. 4B). The first cladding layer 402 is disposed over the single SPAD 401 and along the width (x-direction in the coordinate system of FIG. 4B); and the second cladding layer 406 disposed above a substrate 404 and along the width. A waveguide is provided by selecting materials for the first and second cladding layers 402, 406 having a refractive index that is less than an index of refraction of a core layer. Notably, region 403 between the first and second cladding layers 402, 406 is generally silicon, which is doped in certain regions to provide the various components of the Single SPAD 401. By contrast, the first and second cladding layers 402, 406 each comprise silicon oxide or other suitable material to provide the step in the index of refraction at the interfaces of the region 403 and the first and second cladding layers 402, 406. As such, in certain representative embodiments, region 403 provides the core layer between the first cladding layer 402 and the second cladding layer 406 of the waveguide of detector array. Notably, in accordance with a representative embodiment, the substrate 404 is thinned known backside processing techniques (grinding, chemical mechanical polishing (CMP), etc.) to a desired thickness.

As noted above, the deep n-doped well 102 is formed in the substrate 101, and a high-field (HF) implant 103 is formed over the deep n-doped n-well 102. A resulting avalanche region is formed. Anodes 105 for the respective SPADs are disposed over the HF implant 103, and completes the diode structure. Finally, the independent electrical functions of the Single SPAD 401 is fostered by the inclusion of guard rings 106 disposed around the HF implant 103 and provide electrical isolation of the active region of the Single SPAD 401. As described more fully below, the guard rings 106 have an impact on the overall detection efficient of the photodetector 400. Optically, however, there is no difference between a guard ring 106 and the avalanche region 104 of the Single SPAD 401. However, there is also the top silicon surface (beneath first cladding layer 402) which has active islands (avalanche regions 104) separated by shallow-trench isolation (STI). These different features cause the upper portion of the photodetector 400 optically rough, leading to some photon scattering, which cause additional losses. The degree of such losses depends on various factors such as number of Single SPAD 401 (and thus guard rings 106) and the width/depth of the STI.

The photodetector 400 further comprises an end layer 408 at a distal end of the photodetector 400, and an input waveguide 410 at a proximal end, with an anti-reflective coating 413 disposed between the input waveguide 410 and the silicon of the photodetector 400.

As described below, in operation, the input waveguide 410 fosters reception of photons 412 from a source 414 (e.g., an NIR source of a LiDAR detector) to be guided through the waveguide made up of the core (silicon layer from which the Single SPAD 401 are made) and first and second cladding layers 402, 406.

By contrast, the end layer 408, which is illustratively made of the same material as the first and second cladding layers 402, 406 (e.g., silicon dioxide), provides a step change in the index of refraction at the interface of the region 403 and the end layer 408. As a result, photons 412 incident on the end layer 408 are reflected back towards the input waveguide 410. This improves the probability of a photon that would otherwise be lost, to be incident on an active region of one of the Single SPAD 401, and be absorbed. As such, by providing the end layer 408, the photon detection efficiency of the photodetector 400.

Finally, the input waveguide 410 comprises a geometric structure 420 to decrease reflective losses because of the comparatively larger difference in the indices of refraction at the interface of the SiN waveguide (n˜2) and silicon (n˜3.7) of the photodetector 400. Notably, this geometric structure 420 reduces losses caused by reflections at the interface of the SiN waveguide (n˜2) and silicon (n˜3.7) of the photodetector 400. As alluded to above, the geometric structure 420 is contemplated for use in the various detector arrays described above.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided to comply with 37 C.F.R. § 1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The preceding description of the disclosed embodiments is provided to enable any person skilled in the art to practice the concepts described in the present disclosure. As such, the above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents and shall not be restricted or limited by the foregoing detailed description.

We claim:

1. A detector array (200), comprising:
a substrate (101) adapted to function as a core layer of an optical waveguide (210);
a plurality of single photon avalanche photodiodes (SPADs (201)) disposed in the substrate (101) and along a width of the substrate (101);
a first cladding layer (202) disposed over the plurality of SPADs (201) and along the width; and
a second cladding layer (206) disposed above the substrate (101) and along the width.

2. The detector array (200) of claim 1, wherein the plurality of SPADs (201) comprises a first SPAD (100) along a side of the detector array (200) where radiation is incident, and a last SPAD (100) disposed at an opposing side, wherein the first SPAD (100) has a first width, the last SPAD (100) has a last width, and the first width is smaller than the last width.

3. The detector array (200) of claim 2, wherein the plurality of SPADs (201) further comprises an intermediate SPAD (100) disposed between the first SPAD (100) and the last SPAD (100), wherein the intermediate SPAD (100) has an intermediate width that is greater than the first width and smaller than the last width.

4. The detector array (200) of claim 1, wherein each of the SPADs (201) comprises a junction region (203) having a width in a range of approximately 10 μm to approximately 100 μm and a thickness in a range of approximately 1 μm and approximately 10 μm.

5. The detector array (200) of claim 1, wherein the substrate (101) comprises silicon.

6. The detector array (200) of claim 1, wherein the substrate (101) comprises silicon on insulator (SOI).

7. The detector array (200) of claim 1, further comprising a proximal end adjacent to a light source (214) and adapted to receive light from the light source (214), wherein an input waveguide (210) is disposed at the proximal end, and between the light source (214) and a first SPAD (100).

8. The detector array (200) of claim 7, further comprising an opposing end at an opposing end of the detector array (200) from the proximal end, wherein an end layer (208) comprising a material having an index of refraction that is less than an index of refraction of the core layer is disposed at the opposing end of the detector array (200).

9. A photodetector (400), comprising:
a substrate (101) adapted to function as a core layer of an optical waveguide (210);
a single photon avalanche photodiode (SPAD (100)) disposed along a width of the substrate (101);
a first cladding layer (202) disposed over the single SPAD (401) and along the width; and
a second cladding layer (206) disposed beneath the substrate (101) and along the width, wherein the optical waveguide (210) comprises the substrate (101), the first cladding layer (202) and the second cladding layer (206).

10. The photodetector (400) of claim 9, wherein substrate (101) comprises silicon.

11. The photodetector (400) of claim 9, wherein the substrate (101) comprises silicon on insulator (SOI).

12. The photodetector (400) of claim 9, wherein the SPAD (100) comprises a junction region (203) having a width in a range of approximately 10 μm to approximately 100 μm, and a thickness in a range of approximately 1 μm and approximately 10 μm.

13. The photodetector (400) of claim 9, further comprising a proximal end adjacent to a light source (214) and adapted to receive light from the light source (214), wherein an input waveguide (210) is disposed at the proximal end, and between the input waveguide (210) connected to the light source (214) and the SPAD (100).

14. The photodetector (400) of claim 13, further comprising an opposing end at an opposing end of the photodetector (400) from the proximal end, wherein an end layer comprising a material having an index of refraction that is less than an index of refraction of the core layer is disposed at the opposing end of the photodetector (400).

15. The photodetector (400) of claim 9, wherein the substrate (101) comprises silicon.

16. The photodetector (400) of claim 9, wherein the substrate (101) comprises silicon on insulator (SOI).
